(19) United States
(12) Patent Application Publication
(10) Pub. No.: US 2013/0105206 A1
(43) Pub. Date: May 2, 2013

(54) TRANSPARENT PANEL AND METHOD OF MANUFACTURING THE SAME

(71) Applicants: Jae Il KIM, Yongin (KR); Jong Young Lee, Suwon (KR); Sang Hwa Kim, Suwon (KR)

(72) Inventors: Jae Il KIM, Yongin (KR); Jong Young Lee, Suwon (KR); Sang Hwa Kim, Suwon (KR)

(73) Assignee: Samsung Electro-Mechanics Co., Ltd., Suwon (KR)

(21) Appl. No.: 13/616,804

(22) Filed: Sep. 14, 2012

(30) Foreign Application Priority Data
Oct. 28, 2011 (KR) 10-2011-0111271

(51) Int. Cl. H05K 1/09; B05D 5/12

(52) U.S. Cl. 174/257; 427/108

(57) ABSTRACT

There are provided a transparent panel and a method of manufacturing the same. The transparent panel includes: a transparent substrate; a conductive polymer layer formed over the entirety of a surface of the transparent substrate; and a refractive index matching layer formed in at least some regions of the conductive polymer layer, wherein the at least some regions in which the refractive index matching layer is formed correspond to regions in which electrical conductivity is inactivated in the conductive polymer layer. According to the present invention, the conductive polymer layer is formed on at least one surface of the transparent substrate and the electrical conductivity is inactivated in at least some regions of the conductive polymer layer to form sensing electrodes having a predetermined pattern, and the refractive index matching layer is formed in the at least some regions in which the electrical conductivity is inactivated.

### CROSS-REFERENCE TO RELATED APPLICATIONS

This application claims the priority of Korean Patent Application No. 10-2011-0111271 filed on Oct. 28, 2011, in the Korean Intellectual Property Office, the disclosure of which is incorporated herein by reference.

### BACKGROUND OF THE INVENTION

1. Field of the Invention

The present invention relates to a transparent panel in which electrical conductivity is inactivated in at least certain regions of a conductive polymer layer formed on one surface of a transparent substrate to form an electrode having a predetermined pattern, and a refractive index matching layer is formed in the regions in which the electrical conductivity is inactivated, such that the pattern may be prevented from being visible and the electrode may be formed without a step, and a method of manufacturing the same.

2. Description of the Related Art

A transparent panel, an apparatus manufactured by forming electrodes having a predetermined pattern using a transparent conductive material having excellent light transmissivity on a transparent substrate also having excellent light transmissivity, is widely used in a flat panel display (FPD) such as a liquid crystal display (LCD) or an organic light emitting diode (OLED) display device, and in an input apparatus such as a touch screen, or the like. Particularly, recently, as a majority of home televisions are produced as a flat panel display and users of smart phones, navigation apparatuses, and the like, including a touch screen as an input apparatus steadily increase, the demand for a transparent panel has also increased.

Touch screens used in electronic devices maybe largely divided into resistive type touch screens and capacitive type touch screens, according to a method of sensing a touch. Of these, the capacitive type touch screen has advantages in that it has a relatively long lifespan and various input methods may be easily implemented therein, such that an adoption rate thereof has markedly increased. Particularly, a multi-touch interface may more easily be implemented in the capacitive type touch screen, as compared to the resistive type touch screen, such that the capacitive type touch screen is widely used in devices such as smart phones, and the like.

Both the resistive type touch screen and the capacitive type touch screen include a transparent substrate and a transparent electrode formed on one surface of the transparent substrate. The transparent electrode may generally be formed by depositing a transparent conductive material such as indium tin oxide (ITO), zinc oxide (ZnO), indium zinc oxide (IZO), or the like, on one surface of the transparent substrate in a scheme such as a sputtering scheme, or the like, and then etching the deposited transparent conductive material to have a desired pattern. However, in this case, regions in which the transparent conductive material is formed and regions in which the transparent conductive material is removed are present on one surface of the transparent substrate, such that pattern visibility may occur due to differences in light transmissivity and refractive index between the transparent electrode and the transparent substrate.

### SUMMARY OF THE INVENTION

An aspect of the present invention provides a transparent substrate in which a conductive polymer layer is formed on one surface of a transparent substrate, electrical conductivity is inactivated in at least some regions of the conductive polymer layer in order to pattern a transparent electrode, and a refractive index matching layer is formed on the at least some regions of the conductive polymer layer in which the electrical conductivity is inactivated, such that the transparent electrode may be formed without a step and pattern visibility may be significantly reduced, and a method of manufacturing the same.

According to an aspect of the present invention, there is provided a transparent panel including: a transparent substrate; a conductive polymer layer formed over the entire surface of the transparent substrate; and a refractive index matching layer formed in at least some regions of the conductive polymer layer, wherein the at least some regions in which the refractive index matching layer is formed correspond to regions in which electrical conductivity is inactivated in the conductive polymer layer.

The conductive polymer layer may include a first region having electrical conductivity and a second region in which electrical conductivity is inactivated, and the first and second regions may have the same thickness.

The first and second regions of the conductive polymer layer may have different sheet resistance values.

The first and second regions of the conductive polymer layer have a ratio of a light absorption rate of 80 to 120% therebetween.

The reflective index matching layer may include ultraviolet (UV) ink.

The conductive polymer layer may include at least one of polythiophene, poly(3,4-ethylene dioxythiophene) (PEDOT), polyaniline, polypyrrole, and polyacetylene.

According to another aspect of the present invention, there is provided a method of manufacturing a transparent panel, the method including: preparing a transparent substrate; forming a conductive polymer layer on at least one surface of the transparent substrate; inactivating electrical conductivity in at least some regions of the conductive polymer layer; and forming a refractive index matching layer in the at least some regions in which the electrical conductivity is inactivated.

The forming of the conductive polymer layer may include forming the conductive polymer layer over the entirety of the at least one surface of the transparent substrate.

The inactivating of the electrical conductivity may include inactivating the electrical conductivity by processing the at least some regions of the conductive polymer layer using an oxidizing agent.

The oxidizing agent may include at least one of sodium hypochlorite (NaOCl), potassium permanganate (KMnO₄), potassium dichromate (K₂Cr₂O₇), and amino acid.

The inactivating of the electrical conductivity may include inactivating the electrical conductivity by performing a thermal treatment on the at least some regions of the conductive polymer layer.

The inactivating of the electrical conductivity may include performing the thermal treatment on the at least some regions of the conductive polymer layer at a temperature of 50 to 150° C. for 5 seconds to 60 minutes.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view showing an exterior of an electronic device including a transparent panel according to an embodiment of the present invention;

FIG. 2 is a view showing a touch screen including a transparent panel according to an embodiment of the present invention;

FIG. 3 is a cross-sectional view of a transparent panel according to an embodiment of the present invention;

FIG. 4 is a view illustrating a method of manufacturing a transparent panel according to an embodiment of the present invention;

FIG. 5 is a flowchart illustrating a method of manufacturing a transparent panel according to an embodiment of the present invention; and

FIG. 6 is a graph illustrating characteristics of a transparent panel according to an embodiment of the present invention.

### DETAILED DESCRIPTION OF THE INVENTION

Embodiments of the present invention will be described in detail with reference to the accompanying drawings. These embodiments will be described in detail in order to allow those skilled in the art to practice the present invention. It should be appreciated that various embodiments of the present invention are different, but are not necessarily exclusive.

For example, specific shapes, configurations, and characteristics described in an embodiment of the present invention may be implemented in another embodiment without departing from the spirit and the scope of the present invention. In addition, it should be understood that positions and arrangements of individual components in each disclosed embodiment may be changed without departing from the spirit and the scope of the present invention. Therefore, the detailed description provided below should not be construed as being restrictive. In addition, the scope of the present invention is defined only by the accompanying claims and their equivalents if appropriate. Similar reference numerals will be used to describe elements having the same or similar functions throughout the accompanying drawings.

Hereinafter, embodiments of the present invention will be described in detail with reference to the accompanying drawings so that those skilled in the art may easily practice the present invention.

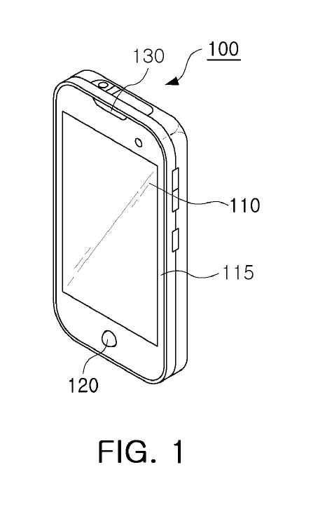

FIG. 1 is a view showing an electronic device in which a transparent panel according to an embodiment of the present invention is applicable. Referring to FIG. 1, an electronic device 100 according to the present embodiment may include a display apparatus 110 for outputting an image, an input unit 120, an audio unit 130 for outputting audio, and a touch sensing apparatus integrated with the display apparatus 110. In this case, the transparent panel suggested in the present invention may be used in a touch sensing apparatus provided as a touch screen as well as the display apparatus 110.

As shown in FIG. 1, in the case of a mobile apparatus, the touch sensing apparatus is generally provided integrally with the display device, and needs to have high light transmissivity enough to transmit the image displayed by the display apparatus. Therefore, the transparent panel included in the touch sensing apparatus may be implemented by forming a transparent electrode using a conductive polymer having electrical conductivity on a transparent substrate formed of a material having excellent light transmissivity such as polyethylene terephthalate (PET), polycarbonate (PC), polyethersulfone (PES), polyimide (PI), tempered glass, or the like. The display apparatus may include a wiring pattern disposed in a bezel region 115 thereof, wherein the wiring pattern is connected to the sensing electrode formed of the transparent conductive material. Since the wiring pattern is visually shielded by the bezel region 115, it may be formed of a metal material such as silver (Ag), copper (Cu), or the like.

According to the present embodiment, the conductive polymer used to form the transparent electrode may include at least one of polythiophene, poly(3,4-ethylene dioxythiophene) (PEDOT), polyaniline, polypyrrole, and polyacetylene. The conductive polymer may have a sheet resistance level of several hundreds of Ω/sq and be formed on one surface of the transparent substrate. As an example, a conductive polymer layer may be formed over the entirety of one surface of the transparent substrate, and electrical conductivity may be inactivated in at least some regions of the conductive polymer layer in order to form an electrode having a desired pattern.

Hereinafter, a case in which the transparent panel according to the present embodiment is used in a touch screen will be described for convenience of explanation. However, it is to be noted that the transparent panel according to the present embodiment may be used in various apparatuses other than the touch screen.

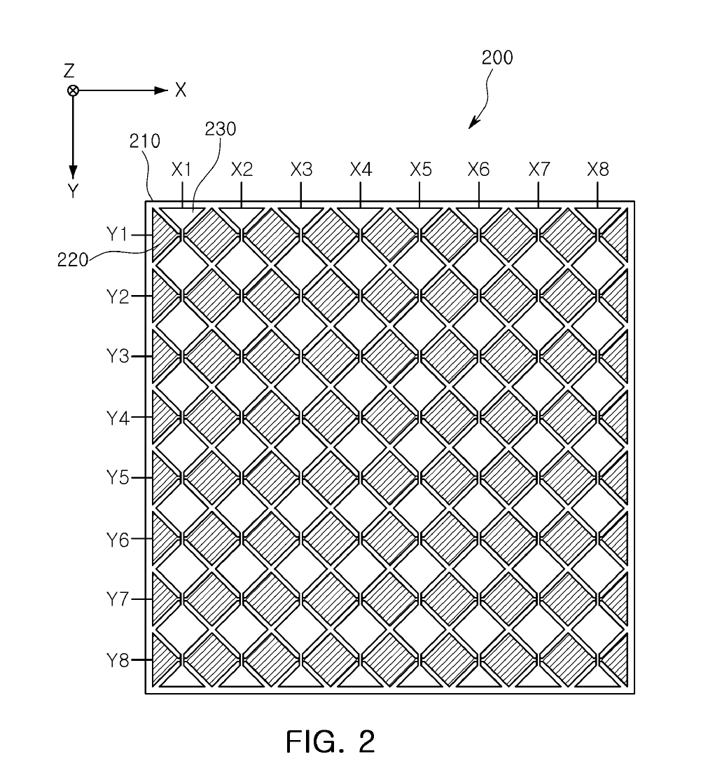

FIG. 2 is a view showing a touch screen including the transparent panel according to the embodiment of the present invention. A touch screen 200 shown in FIG. 2 may include a transparent substrate 210 and a plurality of sensing electrodes 220 and 230 formed on the transparent substrate 210. The plurality of sensing electrodes 220 and 230 may include first electrodes 220 for sensing a position of a touch in a Y-axis direction and second electrodes 230 for sensing a position of a touch in an X-axis direction. In FIG. 2, it is assumed that eight first electrodes 220 and eight second electrodes 230 are included and the first and second electrodes 220 and 230 are connected to sensing channels X1 to X8 and Y1 to Y8 of a controller chip judging the touch, respectively.

Although FIG. 2 shows that the first and second electrodes 220 and 230 are formed on the same surface of the transparent substrate 210, the first and second electrodes 220 and 230 may be separately formed on upper and lower surfaces of the transparent substrate 210, respectively, or be formed on a plurality of transparent substrates. That is, a plan view of the touch screen shown in FIG. 2 is only an example for describing the transparent panel according to the embodiment of the present invention, and the transparent panel according to the embodiment of the present invention may be included in a touch screen having a different structure from that of FIG. 2.

Referring to FIG. 2, the plurality of sensing electrodes 220 and 230 may be formed on the transparent substrate 210 and be patterned so that a specific shape repeatedly appears. In

FIG. 2 the sensing electrodes 220 and 230 are pattered such that unit electrodes having a diamond or rhombus shape are connected to each other in an X-axis or Y-axis direction to thereby be continuously disposed. According to the present embodiment, a conductive polymer layer is formed on one surface of the transparent substrate 210, and electrical conductivity is inactivated in some regions of the conductive polymer layer, whereby the sensing electrodes 220 and 230 having the patterns as shown in FIG. 2 may be formed.

The first electrodes 220 for sensing the position of the touch in the Y-axis direction and the second electrodes 230 for sensing the position of the touch in the X-axis direction may be formed in a manner such that empty regions between the plurality of first electrodes 220 are filled with the plurality of second electrodes 230 and empty regions between the plurality of second electrodes 230 are filled with the plurality of first electrodes 220 as shown in FIG. 2. Therefore, electrical conductivity of a first conductive polymer layer used to form the plurality of first electrodes 220 may be inactivated in regions in which the plurality of second electrodes 230 are formed, and electrical conductivity of a second conductive polymer layer used to form the plurality of second electrodes 230 may be inactivated in regions in which the plurality of first electrodes 220 are formed.

Meanwhile, a predetermined reflective index matching layer may be formed in the regions of the first and second conductive polymer layers in which electrical conductivity is inactivated. The refractive index matching layer maybe formed in order to prevent pattern visibility of the sensing electrodes 220 and 230 due to a difference in refractive index between the regions in which electrical conductivity is inactivated and the regions in which electrical conductivity is activated, and may include a material in which dye, pigment, or the like, is mixed with ultraviolet (UV) ink. As described above, the refractive index matching layer is formed in the regions in which electrical conductivity is inactivated in the conductive polymer layer to limit a light absorption rate between the regions in which electrical conductivity is inactivated and the regions in which electrical conductivity is activated to be in the range of 80 to 120%, whereby the pattern visibility of the sensing electrodes 220 and 230 may be significantly reduced.

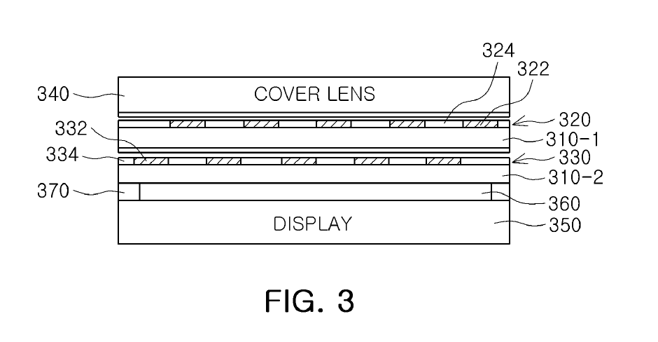

FIG. 3 is a cross-sectional view of a transparent panel according to an embodiment of the present invention. Referring to FIG. 3, a transparent panel 300 according to the present embodiment may include a first substrate 310-1, a second substrate 310-2, a first conductive polymer layer 320 formed on the first substrate 310-1, and a second conductive polymer layer 330 formed on the second substrate 310-2. Hereinafter, a case in which the transparent panel 300 according to the present embodiment is used in the touch screen will be described for convenience of explanation, similar to FIG. 2.

The transparent panel 300 may include a display apparatus 350 adhered to a lower portion thereof by a gasket 370, having an air gap 360 therebetween, and include a cover lens 340 formed on an upper portion thereof, wherein the cover lens 340 is formed of an acrylic material such as tempered glass or PMMA. The air gap formed between the transparent panel 300 and the display apparatus 350 may reduce electrical noise generated in the display apparatus 350 to thereby be transferred to the transparent panel 300.

The first conductive polymer layer 320 on which first electrodes for sensing a position of a touch in a Y-axis direction is to be formed may be formed on the first substrate 310-1, and the second conductive polymer layer 330 on which second electrodes for sensing a position of a touch in an X-axis direction is to be formed may be formed on the second substrate 310-2. As shown in FIG. 3, the first and second conductive polymer layers 320 and 330 may include respective first regions 322 and 332 used as sensing electrodes since electrical conductivity of the first and second conductive polymer layers 320 and 330 is maintained therein and respective second regions 324 and 334 in which electrical conductivity thereof is inactivated. The first regions 322 of the first conductive polymer layer 320 and the first regions 332 of the second conductive polymer layer 330 may be disposed to be alternate with each other. As shown in FIG. 2, the empty regions between the first electrodes may be filled with the second electrodes.

The first and second substrates 310-1 and 310-2 may be formed of a material having excellent light transmissivity such as polyethylene terephthalate (PET), polycarbonate (PC), polyethersulfone (PES), polyimide (PI), tempered glass, or the like, as described above. When the first and second conductive polymer layers 320 and 330 are formed and electrical conductivity is inactivated in some regions 324 and 334 thereof to thereby form the first and second electrodes, respectively, the first and second substrates 310-1 and 310-2 may be adhered to each other by a transparent adhesive layer such as an optical clear adhesive (OCA).

As shown in FIG. 3, the first and second conductive polymer layers 320 and 330 may be formed over the entirety of one surface of the first and second substrates 310-1 and 310-2, respectively, and include some regions in which the electrical conductive is inactivated, thereby forming the first and second electrodes. In addition, since the second regions 324 and 334 in which electrical conductivity is inactivated may be formed only through chemical treatment without performing an etching process of physically removing the conductive polymer material, electrical conductivity may be inactivated in the second regions 324 and 334 without damaging the first and second substrates 310-1 and 310-2. In addition, since the physical etching process is not included, the first regions 322 and 332 and the second regions 324 and 334 may have the same thickness.

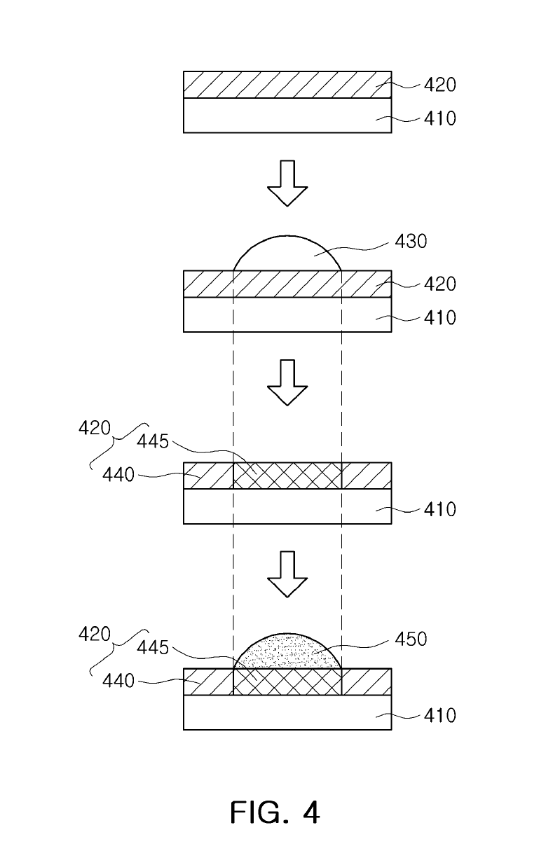

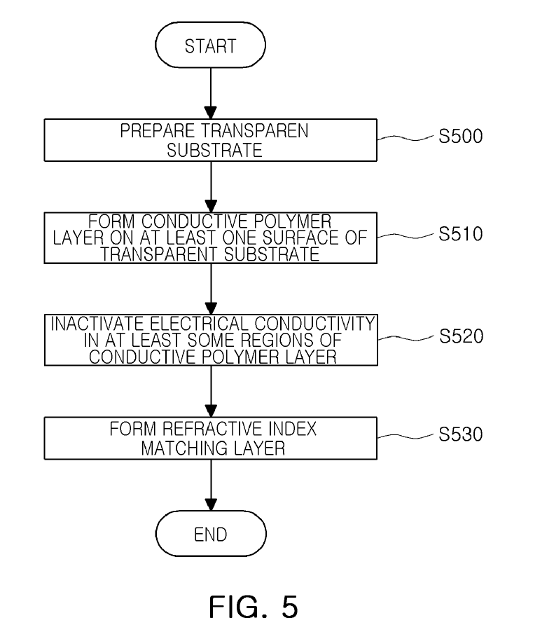

FIG. 4 is a view provided in order to describe a method of manufacturing a transparent panel according to an embodiment of the present invention; and FIG. 5 is a flowchart provided in order to describe a method of manufacturing a transparent panel according to an embodiment of the present invention. Hereinafter, the transparent panel and the method of manufacturing the same according to the embodiment of the present invention will be described with reference to FIGS. 4 and 5.

Referring to FIGS. 4 and 5, a method of manufacturing a transparent panel according to the present embodiment starts with preparing a transparent substrate 410 (S500). The transparent substrate 410 may be formed of a material having excellent light transmissivity such as polyethylene terephthalate (PET), polycarbonate (PC), polyethersulfone (PES), polyimide (PI), tempered glass, or the like.

After the transparent substrate 410 is prepared, a conductive polymer layer 420 is formed on at least one surface of the transparent substrate 410 (S510). Referring to FIG. 4, the conductive polymer layer 420 may be formed on one surface of the transparent substrate 410. Particularly, the conductive polymer layer 420 may be formed to cover the entirety of one surface of the transparent substrate 410. As described above, the conductive polymer layer 420 may include at least one of polythiophene, poly(3,4-ethylene dioxythiophene) (PEDOT), polyaniline, polypyrrole, and polyacetylene.

After the conductive polymer layer 420 is formed, electrical conductivity is inactivated in at least some regions of the conductive polymer layer 420 (S520). As shown in FIG. 4, in order to inactivate electrical conductivity in some regions of the conductive polymer layer, a chemical etching process is performed thereon. That is, an oxidation process is performed on some regions of the conductive polymer layer 420 using an etchant 430, whereby electrical conductivity may be inactivated therein.

The inactivating of electrical conductivity of the conductive polymer layer 420 in operation 5520 may include processing some regions of the conductive polymer layer 420 using an oxidizing agent 430. Here, the oxidizing agent may include at least one of sodium hypochlorite (NaOCl), potassium permanganate (KMnO₄), potassium dichromate (K₂Cr₂O₇), and amino acid. When it is assumed that the conductive polymer layer 420 includes poly-(3,4-ethylene dioxythiophene) (PEDOT) and sodium hypochlorite (NaOCl) is used as the oxidizing agent 430, electrical conductivity is inactivated through a process as represented by the following Chemical Formula 1:

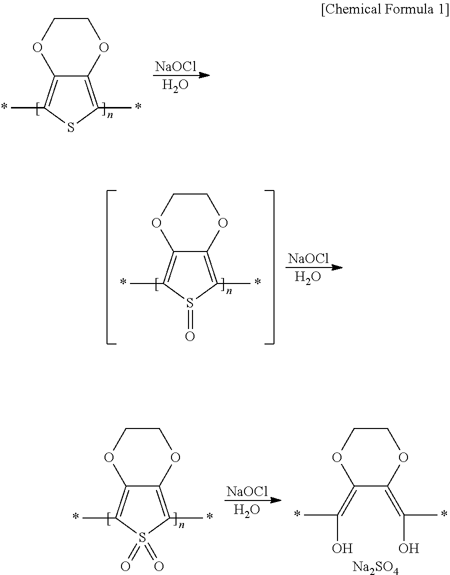

Referring to Chemical Formula 1, a thiophene ring is included in a chemical structure of PEDOT, and bonding of the thiophene ring is partially broken by performing oxidation using sodium hypochlorite and water, such that electrical conductivity is inactivated. Therefore, the conductive polymer layer 420 shown in FIG. 4 includes a first region 440 having electrical conductivity and a second region 445 in which electrical conductivity is inactivated. As an example, the inactivating of electrical conductivity in operation S520 may further include performing thermal treatment on at least some regions of the conductive polymer layer at a temperature of 50 to 150° C. for 5 seconds to 60 minutes.

The first region 440 having electrical conductivity and the second region 445 in which electrical conductivity is inactivated have different light transmissivities and refractive indices. Therefore, a boundary between the first region 440 and the second region 445 may be visually discerned by a user, whereby pattern visibility may occur. In order to significantly reduce or prevent the pattern visibility, a refractive index matching layer 450 may be formed in the second region 445 (S530). The refractive index matching layer 450 may include a mixture of UV ink and dye, or the like.

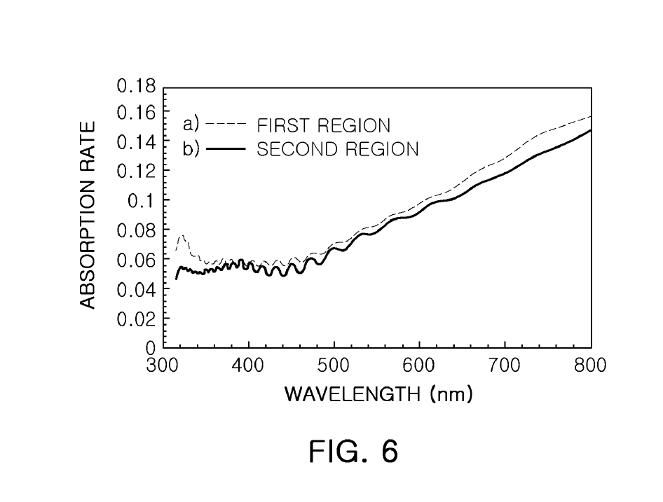

FIG. 6 is a graph provided in order to describe characteristics of a transparent panel according to an embodiment of the present invention. Referring to FIG. 6, a light absorption rate (denoted by a dotted line) of the second region 445, in which electrical conductivity is inactivated and the refractive index matching layer 450 is formed, and a light absorption rate (denoted by a solid line) of the first region 440 having electrical conductivity are shown according to a wavelength of light.

A wavelength of light within a visible region, able to be visually discerned by a person, may be in the range of 380 nm to 780 nm. Therefore, as shown in FIG. 6, the light absorption rates in the wavelength included in the visible region of light appear to be almost the same and a difference between the light absorption rates in a wavelength close to an infrared (about 700 nm to 800 nm) representing the largest difference between the light absorption rates is limited to 10% if preferable. The pattern visibility due to the difference in the light absorption rates between the first and second regions 440 and 445 may therefore be significantly reduced.

As set forth above, according to embodiments of the present invention, a conductive polymer layer is formed on one surface of a transparent substrate, electrical conductivity is inactivated in at least some regions of the conductive polymer layer, and a refractive index matching layer is then formed in the regions in which electrical conductivity is inactivated. Therefore, a transparent electrode may be formed without a step and pattern visibility may be significantly reduced.

While the present invention has been shown and described in connection with the embodiments, it will be apparent to those skilled in the art that modifications and variations can be made without departing from the spirit and scope of the invention as defined by the appended claims.

What is claimed is:

1. A transparent panel comprising:
a transparent substrate;
a conductive polymer layer formed on the transparent substrate; and
a refractive index matching layer formed in at least some regions of the conductive polymer layer,
wherein the at least some regions in which the refractive index matching layer is formed correspond to regions in which electrical conductivity is inactivated in the conductive polymer layer.

2. The transparent panel of claim 1, wherein the conductive polymer layer includes a first region having electrical conductivity and a second region in which electrical conductivity is inactivated, and
the first and second regions have the same thickness.

3. The transparent panel of claim 2, wherein the first and second regions of the conductive polymer layer have different sheet resistance values.

4. The transparent panel of claim 3, wherein the first and second regions of the conductive polymer layer have a ratio of a light absorption rate of 80 to 120% therebetween.

5. The transparent panel of claim 1, wherein the reflective index matching layer includes ultraviolet (UV) ink.

6. The transparent panel of claim 1, wherein the conductive polymer layer includes at least one of polythiophene, poly(3,4-ethylene dioxythiophene) (PEDOT), polyaniline, polypyrrole, and polyacetylene.

7. A method of manufacturing a transparent panel, the method comprising:
preparing a transparent substrate;
forming a conductive polymer layer on at least one surface of the transparent substrate;
inactivating electrical conductivity in at least some regions of the conductive polymer layer; and
forming a refractive index matching layer in the at least some regions in which the electrical conductivity is inactivated.

8. The method of claim 7, wherein the forming of the conductive polymer layer includes forming the conductive polymer layer over the entirety of the at least one surface of the transparent substrate.

9. The method of claim 7, wherein the inactivating of the electrical conductivity includes inactivating the electrical conductivity by processing the at least some regions of the conductive polymer layer using an oxidizing agent.

10. The method of claim 9, wherein the oxidizing agent includes at least one of sodium hypochlorite (NaOCl), potassium permanganate (KMnO₄), potassium dichromate (K₂Cr₂O₇), and amino acid.

11. The method of claim 7, wherein the inactivating of the electrical conductivity includes inactivating the electrical conductivity by performing a thermal treatment on the at least some regions of the conductive polymer layer.

12. The method of claim 11, wherein the inactivating of the electrical conductivity includes performing the thermal treatment on the at least some regions of the conductive polymer layer at a temperature of 50 to 150° C. for 5 seconds to 60 minutes.
